(19) United States
(12) Patent Application Publication
(10) Pub. No.: US 2025/0191838 A1
(43) Pub. Date: Jun. 12, 2025

(54) BALUN TRANSFORMER WITH ENHANCED RF COUPLING EMBEDDED IN HIGH-STRENGTH DIELECTRIC MATERIALS

(71) Applicant: Lam Research Corporation, Fremont, CA (US)

(72) Inventors: Shen Peng, Dublin, CA (US); James Zu Yi Liu, Sunnyvale, CA (US); Narudha Benyuhmin, Santa Clara, CA (US); Sunil Kapoor, Vancouver, CA (US); Dan Marohl, San Jose, CA (US)

(21) Appl. No.: 18/833,859

(22) PCT Filed: Feb. 3, 2023
(86) PCT No.: PCT/US2023/012347

§ 371 Date: Jul. 26, 2024

Related U.S. Application Data
(60) Provisional application No. 63/309,483, filed on Feb. 11, 2022.

(51) Int. Cl. H01F 30/10; H01F 27/28; H01F 27/32; H01J 37/32

(52) U.S. Cl. CPC H01F 30/10; H01F 27/2852; H01F 27/327; H01J 37/32183; H01J 37/321

(57) ABSTRACT

A balun transformer for use in powering an electrode coil of a semiconductor chamber is provided. In one example, the balun transformer includes a primary coil having a primary winding between a primary first end and a primary second end. The primary winding defined from a primary rectangular conductor. The balun transformer includes a secondary coil having a secondary winding between a secondary first end and a secondary second end. The secondary winding defined from a secondary rectangular conductor. The primary rectangular conductor and the secondary rectangular conductor are interleaved in a spaced apart orientation, such that one or two sides of each of the primary rectangular conductor and the secondary rectangular conductor are adjacent to one another.

### BACKGROUND

### 1. Field of the Invention

The present embodiments relate to semiconductor fabrication, and more particularly to systems and methods for incorporating balun transformers to transfer power to inductively coupled plasma sources of a plasma processing system.

### 2. Description of the Related Art

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to plasma generated within a plasma processing volume. Plasma contains various types of radicals, electrons, as well as positive and negative ions. The chemical reactions of the various radicals, electrons, positive ions, and negative ions are used to etch features, surfaces and materials of a wafer.

For example, when a process gas is supplied into the plasma processing chamber, a radio frequency (RF) signal is applied to at least one of the electrodes of the plasma processing chamber to form an electric field between the electrodes. The process gas is turned into plasma by the RF signal, thereby performing plasma etching on a predetermined layer disposed on the wafer. Unfortunately, as the demand to etch ever shrinking features and higher aspect ratio geometries continues to increase, there is a corresponding demand for higher power systems that can precision etch deeper features while maintaining etch uniformity across the wafer.

It is in this context that embodiments of the inventions arise.

### SUMMARY

Implementations of the present disclosure include devices, methods, and systems for improving etch uniformity of features over a wafer, while also providing for improved etch rates using high radio frequency (RF) power levels. In one embodiment, balun transformers are used to efficiently transfer power to a transformer coupled plasma (TCP) coil of a plasma processing system.

In some embodiments, each balun transformer may include a primary coil having a primary winding and a secondary coil having a secondary winding. The primary winding is defined from a primary rectangular conductor and the secondary winding is defined from a secondary rectangular conductor where the primary rectangular conductor and the secondary rectangular conductor are interleaved in a spaced apart orientation. It has been observed that by having the primary winding and secondary winding maintain rectangular shaped configurations, this enables the respective coils to be in closer proximity to one another. As will be described below, the rectangular shape provides for an increase of surface area facing each other between the respective primary and secondary windings. Accordingly, in one embodiment, by enabling the respective coils of the balun transformer to be in close proximity to one another, this can improve RF coupling between the primary coil and the secondary coil which can result in a greater amount of power transferring to the TCP coils. Thus, during plasma processing operations, the rectangular shape of the primary coil and secondary coil of the balun transformer can enable enhanced performance in wafer etch uniformity and power transfer. It should be appreciated that the present embodiments can be implemented in numerous ways, e.g., a process, an apparatus, a system, a device, or a method on a computer readable medium. Several embodiments are described below.

In one embodiment, a balun transformer for use in powering an electrode coil of a semiconductor chamber is disclosed. The balun transformer includes a primary coil having a primary winding between a primary first end and a primary second end. The primary winding defined from a primary rectangular conductor. The balun transformer includes a secondary coil having a secondary winding between a secondary first end and a secondary second end. The secondary winding defined from a secondary rectangular conductor. The primary rectangular conductor and the secondary rectangular conductor are interleaved in a spaced apart orientation, such that one or two sides of each of the primary rectangular conductor and the secondary rectangular conductor are adjacent to one another.

In another embodiment, a system for powering a first electrode coil and a second

electrode coil of a semiconductor chamber is disclosed. The system includes a process chamber. The process chamber includes a dielectric window that is oriented over a substrate support. The system includes a coil defined by a first electrode coil and a second electrode coil. The coil oriented over the dielectric window. The system includes a first balun transformer for connecting to the first electrode coil. The first balun transformer includes a first primary coil having a first primary winding. The first primary winding defined from a first primary rectangular conductor. The first balun transformer includes a first secondary coil having a first secondary winding. The first secondary winding defined from a first secondary rectangular conductor. The first primary rectangular conductor and the first secondary rectangular conductor are interleaved in a spaced apart orientation, such that one or two sides of each of the first primary rectangular conductor and the first secondary rectangular conductor are adjacent to one another. The system includes a second balun transformer for connecting to the second electrode coil. The second balun transformer includes a second primary coil having a second primary winding. The second primary winding defined from a second primary rectangular conductor. The second balun transformer includes a second secondary coil having a second secondary winding. The second secondary winding defined from a secondary rectangular conductor. The second primary rectangular conductor and the second secondary rectangular conductor are interleaved in a spaced apart orientation, such that one or two sides of each of the second primary rectangular conductor and the second secondary rectangular conductor are adjacent to one another.

Several advantages of the herein described systems and methods for etching a wafer in a plasma system where the etch uniformity of features along a wafer is improved by integrating balun transformers within the TCP coil circuit of a of a plasma processing system. Instead of configuring the primary coil and the secondary coil to have a round or circular cross-section, by configuring the primary coil and the secondary coil such that its corresponding cross-section shape is primarily rectangular, this can enable the respective coils to be placed more proximate to one another and can also further provide a greater surface area. As such, improvements in RF coupling during processing operations can be achieved which in turn can result in improvements in etch uniformity of features along a wafer.

Other aspects and advantages of the disclosure will become apparent from the following detailed description, taken in conjunction with the accompanying drawings, illustrating by way of example the principles of the disclosure.

### BRIEF DESCRIPTION OF THE DRAWINGS

The disclosure may be better understood by reference to the following description taken in conjunction with the accompanying drawings in which:

FIG. 1 illustrates a transformer coupled plasma (TCP) system, which is an example type of inductively coupled plasma (ICP) processing system, in accordance with an implementation of the disclosure.

FIG. 2A illustrates an embodiment of a balun transformer, in accordance with an implementation of the disclosure.

FIG. 2B illustrates a top view of the balun transformer shown in FIG. 2A, in accordance with an implementation of the disclosure.

FIG. 3A illustrates a partial cross-sectional view of the balun transformer taken along line A-A of FIG. 2B, in accordance with an implementation of the disclosure.

FIG. 3B illustrates an enlarged partial view of a section of the balun transformer 102a shown in FIG. 3A, in accordance with an implementation of the disclosure.

FIG. 4 is a schematic diagram illustrating the circuit topology of a TCCT match circuitry coupled between an RF generator and TCP coils 110 of a plasma processing system, in accordance with an implementation of the disclosure.

FIG. 5 is a schematic illustrating a portion of the plasma processing system, in accordance with an implementation of the disclosure.

FIG. 6 shows an example schematic of the control system of FIG. 1, in accordance with an implementation of the disclosure.

### DETAILED DESCRIPTION

The following implementations of the present disclosure provide devices, methods, and systems for enhancing (radio frequency) RF power efficiency by using balun transformers to transfer power to coils of an inductively coupled plasma (ICP) system. In one embodiment, the ICP is a transformer coupled plasma (TCP) system. In one embodiment, two balun transformers are provided, each balun transformer includes a primary coil and a secondary coil where their respective windings are defined by a primary rectangular shaped conductor and a secondary rectangular conductor. In one embodiment, the primary rectangular shaped conductor and the secondary rectangular conductor are interleaved in a spaced apart orientation. The shape and configuration of the primary rectangular conductor and the secondary rectangular conductor enables the respective coils to be in close proximity with one another. A further benefit of the rectangular cross-sectional shape of the windings is an increase in surface area where respective winding surfaces face each other. Accordingly, RF coupling between the respective coils is improved and this provides for a more efficient way to transfer higher power to the respective TCP coils. Advantageously, integrating balun transformers having the rectangular shaped windings provides for greater power transfer to the TCP coils, which in turn can improve etch rates and uniformity for features across a wafer during wafer processing.

With the above overview in mind, the following provides several example figures to facilitate understanding of the example embodiments.

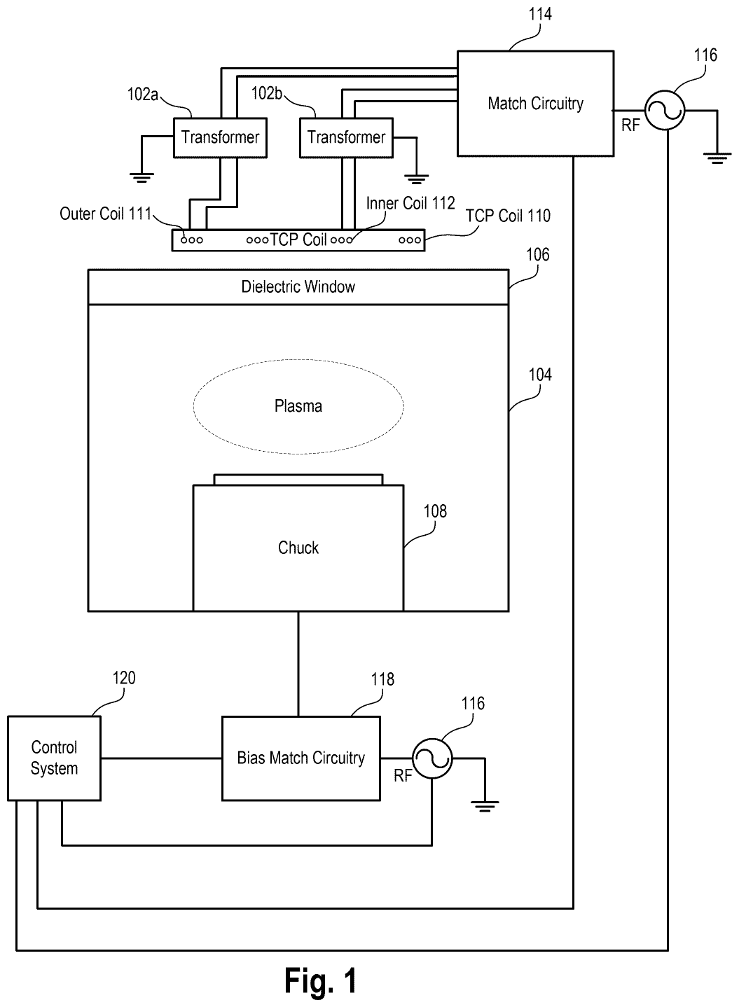

FIG. 1 illustrates a transformer coupled plasma (TCP) system, which is an example type of inductively coupled plasma (ICP) processing system. The TCP system includes balun transformers 102a-102b that are coupled between TCP coils 110 (outer coil 111 and inner coil 112) and a transformer coupled capacitive tuning (TCCT) match circuitry 114. In some embodiments, other types of match circuits can be used. The system further includes a chamber 104 that includes a chuck 108, a dielectric window 106, RF generators 116, a bias match circuitry 118, and a control system 120.

As shown in FIG. 1, in one embodiment, the balun transformers 102a-102b are connected to the TCCT match circuitry 114 and to the TCP coils 110. In particular, balun transformer 102a is connected to the outer coil 111 and balun transformer 102b is connected to the inner coil 112. In one embodiment, when the RF generator 116 is activated, the TCCT match circuitry 114 in combination with the balun transformers 102a-102b can enable dynamic tuning of power provided to the outer coil 111 and the inner coil 112. The outer coil 111 and the inner coil 112 are coupled to the balun transformers 102a-102b which includes connections to the outer coil 111 and the inner coil 112.

In one embodiment, the TCCT match circuitry 114 is configured to tune the TCP coils 110 to provide more power to the inner coil 112 versus the outer coil 111. In another embodiment, the TCCT match circuitry 114 is configured to tune the TCP coils to provide less power to the inner coil 112 versus the outer coil 111. In another embodiment, the power provided to the inner coil 112 and the outer coil 111 will be to provide an even distribution of power and/or control the ion density in a radial distribution over the substrate (i.e., wafer, when present). In yet another embodiment, the tuning of power between the inner coil will and the outer coil can be adjusted based on the processing parameters defined for a specific step in an etching process. In some embodiments, the components of the TCCT match circuitry 114 can be adjusted to reduce reflective power and to maximize delivery of power from the RF generator 116 to the inner coil 112 versus the outer coil 111.

Further shown in FIG. 1 is an RF generator 116, which can be defined by one or more generators. If multiple generators are provided, different frequencies can be used to achieve various etch and tuning characteristics. A bias match circuitry 118 is coupled between the RF generator 116 and a conductive plate of the assembly that defines the chuck 108. The chuck 108 also includes electrostatic electrodes to enable the chucking and dechucking of the wafer, i.e. to enable clamping and unclamping of the wafer from the chuck 108. Other control systems for lifting the wafer off of the chuck 108 can also be provided. Although not shown, pumps are connected to the chamber 104 to enable vacuum control and removal of gaseous byproducts from the chamber 104 during operational plasma processing.

In some embodiments, the dielectric window 106 can be defined from a ceramic type material. For example, the dielectric window 106 can be made from Quartz. Other dielectric materials are also possible, so long as they are capable of withstanding the conditions of a semiconductor etching chamber. The temperature will depend on the etching process operation and specific recipe. The chamber 104 will also operate at vacuum conditions. Although not shown, chamber 104 is typically coupled to facilities when installed in a clean room, or a fabrication facility. Facilities include plumbing that provide processing gases, vacuum, temperature control, and environmental particle control. In some embodiments, these facilities are coupled to chamber 104, when installed in the target fabrication facility. Additionally, chamber 104 may be coupled to a transfer chamber that will enable robotics to transfer semiconductor wafers into and out of the chamber 104 using typical automation.

In some embodiments, the system may include a control system 120 that is used in controlling various components of the plasma processing system. As shown in FIG. 1, the control system 120 may be connected to the bias match circuitry 118, the RF generators 116, and the TCCT Match Circuitry 114. In accordance with one embodiment, the control system 120 may be connected to the TCCT Match Circuitry 114 and the RF generator 116. The control system 120 can be configured to ensure that power is appropriately provided to the outer coils 111 and the inner coils 112.

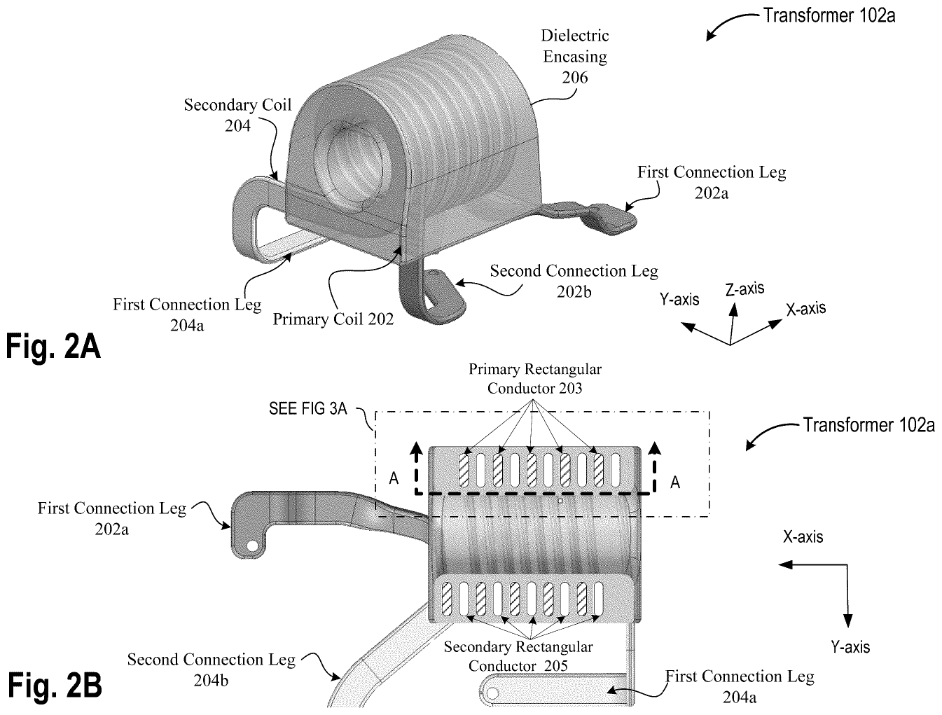

FIG. 2A illustrates an embodiment of a balun transformer 102a and/or 102b. In particular, FIG. 2A illustrates a perspective view of the balun transformer 102a and/or 102b which includes the primary coil 202 and the secondary coil 204 embedded in a dielectric encasing 206. In one embodiment, the primary coil 202 includes a primary winding that is defined by a primary rectangular conductor. Rectangular conductors, as opposed to cylindrical conductors or wires, have a thin side profile with two substantially flattened surfaces which provide more surface area for power transfer. In another embodiment, the secondary coil 204 includes a secondary winding that is defined by a secondary rectangular conductor.

As further illustrated in FIG. 2A, the primary rectangular conductor includes a first connection leg 202a and a second connection leg 202b for electrically connecting to the match circuitry 114 network. The secondary rectangular conductor includes a first connection leg 204a and a second connection leg 204b (not shown) for electrically connecting, respectively, to a first end of the electrode coil and a second end of the electrode coil, e.g., outer coil 111 and inner coil 112. In one embodiment, the primary rectangular conductor of the primary coil 202 and the secondary rectangular conductor of the secondary coil 204 are interleaved in a spaced apart orientation to effectively the transfer RF power to the TCP coils. In one embodiment, by having rectangular shaped conductors where the primary rectangular conductor and the secondary rectangular conductor are interleaved, this enables more facing surface area of the primary coil 202 and secondary coil 204 to be in close proximity to one another which can enable a greater and more effective transfer of RF power to the TCP coils 110. In turn, during processing operations, improvements in etch uniformity of features along a wafer can be achieved having the ability to transfer higher RF power levels.

For example, during plasma etching operations, a TCP system that includes balun transformers 102a-102b coupled between the TCP coils 110 and the TCCT match circuitry 114 can enable the transfer of higher power to the respective TCP coils 110. As described above, the configuration of the rectangular shape of the balun transformers and the increase of surface area between the respective primary and secondary windings of the balun transformers can help facilitate the higher transfer of power to the TCP coils 110. As a result, the higher transfer power of to the TCP coils can precision etch finer detailed features and higher aspect ratio geometries while maintaining etch uniformity across the wafer during wafer processing.

FIG. 2B illustrates a top view of the balun transformer 102a shown in FIG. 2A. As noted above, each balun transformer 102 includes a primary coil 202 and a secondary coil 204 where the primary rectangular conductor 203 portion of the primary coil 202 and the secondary rectangular conductor 205 portion of the secondary coil 204 are interleaved in a spaced apart orientation. As shown, the respective rectangular conductors of the primary coil 202 and the secondary coil 204 are interleaved and arranged in a configuration such that one or two sides of each of the primary rectangular conductor 203 and the secondary rectangular conductor 205 are spaced apart but adjacent to one another.

In one embodiment, the ratio of the number of turns in the primary coil 202 to the number of turns in the secondary coil 204 may vary and depend on the desired voltage and current requirements for the plasma processing system. In the illustrated example shown in FIG. 2B, the turns ratio of the primary coil 202 and the secondary coil 204 of the balun transformer 102a is one to one (1:1). In one embodiment, if the plasma processing system requires a higher voltage and higher current, the number of turns in the secondary coil 204 can be adjusted so that it has a greater number of turns than the primary coil 202. In other embodiments, if the plasma processing system requires a lower voltage and lower current, the number of turns in the secondary coil 204 can be adjusted so that it has a lower number of turns than the primary coil 202.

In one embodiment, the rectangular shape of the primary rectangular conductor 203 portion of the primary coil 202 and the secondary rectangular conductor 205 portion of the secondary coil 204 enables the respective coils to be interleaved and positioned so that surface areas facing each other are in closer proximity to one another, compared to cylindrical coils. During plasma processing operations, this allows the balun transformer 102a/102b to deliver a higher amount of power to the TCP coils 110 more effectively. For example, in one embodiment, the balun transformer 102a can transfer up to about 6,000 Watts to the TCP coils 110, whereby said transferred power is delivered to the plasma in the processing region of the chamber to enable more efficient etching of high aspect ratio features, features that require more precision and/or more uniformity across the wafer between the center of the wafer to the edges of the wafer.

In one embodiment, the primary coil 202 and the secondary coil 204 is made of a continuous conductive wire (e.g., metal-based wire) that is formed into its desired shape using various metal forming/bending techniques. In one example, the primary coil 202 and the secondary coil 204 is made of C110 copper flat bar material. In one embodiment, if the primary coil 202 and the secondary coil 204 are not embedded in a dielectric encasing 206, the coils are silver plated to increase it electrical performance and to help protect the copper material from corrosion and oxidation. In other embodiments, if the primary coil 202 and the secondary coil 204 are embedded in a dielectric encasing 206, the respective coils are not silver plated. In some embodiments, the balun transformer 102a/102b can be fabricated using various techniques. In one example, the primary coil 202 and the secondary coil 204 can be fabricated using a C110 copper flat bar material where a line bending metal forming technique is used achieve the desired configuration, e.g., interleaved and spaced apart. Accordingly, this can enable the substantially flat surfaces of the rectangular conductor 203 and the rectangular conductor 205 to be adjacent and parallel to one another which enables enhanced RF coupling between the primary coil 202 and the secondary coil 204.

In one embodiment, the dielectric encasing 206 is made of a dielectric material (e.g. silicone rubber, or a ceramic) that has a high dielectric constant and is resistant to extreme environments and temperatures. In some embodiments, encasing the primary coil 202 and the secondary coil 204 in the dielectric encasing 206 may help prevent electrical arcing from occurring. For example, the dielectric encasing 206 may include a dense dielectric material surrounding the primary coil 202 and the secondary coil 204 which can provide high dielectric strength while providing high breakdown voltage and minimal gap variation between the primary coil 202 and the secondary coil 204. In one embodiment, the dielectric encasing 206 can be made from a high temperature epoxy potting that has a low viscosity and can be cured fully under a bake process. This can allow voids between the primary coil 202 and the secondary coil 204 to be filled seamlessly. In other embodiments, the dielectric encasing 206 can be made from other materials and depend the desired requirements such as breakdown voltages, material composition, thermal properties, etc. Examples of such materials may include heat-cure epoxies, low coefficient thermal expansion high temperature plastics, low dielectric loss tangent ceramics, or a combination thereof.

In some embodiments, the dielectric encasing 206 can be fabricated using various techniques which may include a molding process. For example, a mold cavity fixture can be designed to encapsulate the primary coil 202 and the secondary coil 204. The mold cavity fixture may include an orifice that is configured to receive a melted dielectric material. Once the melted dielectric material is injected into the orifice of the mold cavity fixture, the dielectric encasing 206 is created after the melted dielectric material hardens. After the melted dielectric material hardens, the mold cavity fixture is removed which results in the primary coil 202 and the secondary coil 204 being embedded in the dielectric encasing 206.

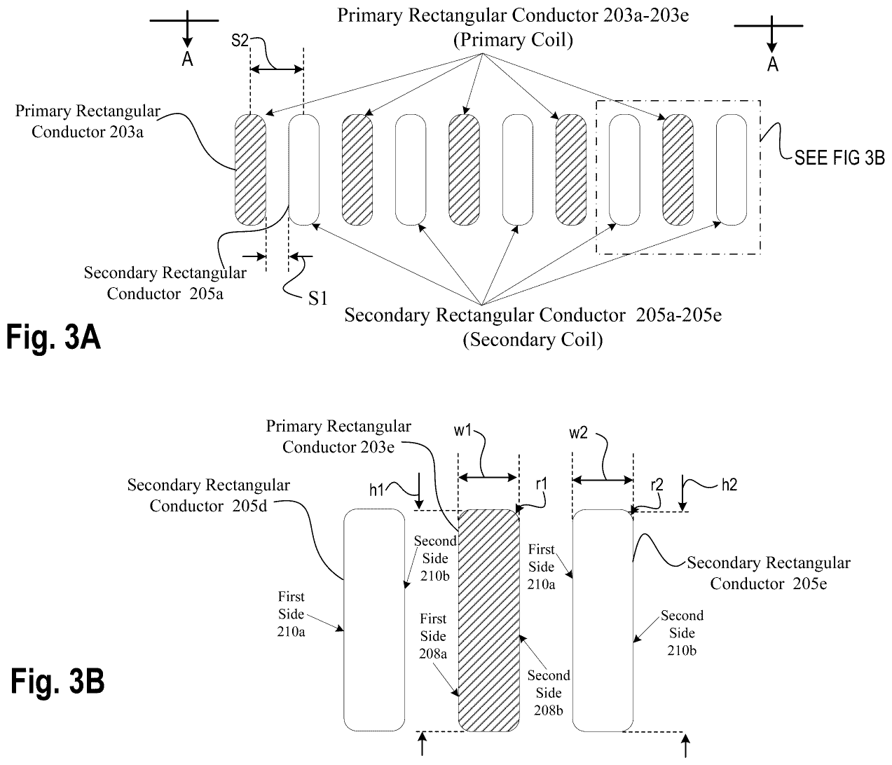

FIG. 3A illustrates a partial cross-sectional view of the balun transformer 102a taken along line A-A of FIG. 2B. As illustrated, the primary rectangular conductor 203a-203e and the secondary rectangular conductor 205a-205e are interleaved in a spaced apart orientation. The configuration and shape of the respective rectangular conductors can enable the primary coil and secondary coil to be in close proximity to one another which improves RF coupling between the primary coil and secondary coil. In other embodiments, the shape of the primary rectangular conductor 203 and the secondary rectangular conductor 205 may be an oval shape or any other shape that can enable the conductors to be oriented in close proximity to one another and have sufficient surface area to enable an effective transfer of RF power. Otherwise, for example, if the shape of the primary rectangular conductor 203 and the secondary rectangular conductor 205 were circular, the surface area facing the respective conductors would be less than the respective area of the rectangular shaped conductors for a given separation distance between the conductors. Thus, for circular shaped conductors, their respective surface areas would not be as sufficient to enable an effective transfer of RF power compared to the rectangular shaped conductors.

As illustrated in FIG. 3A, distance S1 is defined by a distance extending from a second side of primary rectangular conductor 203a to a first side of secondary rectangular conductor 205a. In one embodiment, distance S1 can range from about 2 mm and 6 mm. In one example, distance S1 is about 4 mm. Distance S2 is defined by a distance extending from the centerline of the primary rectangular conductor 203a to the centerline of the secondary rectangular conductor 205a. In one embodiment, distance S2 can range from about 5 mm and about 12 mm. In one example, distance S2 is about 7 mm. By maintaining reduced distance S1, RF coupling between the primary coil 202 and the secondary coil 204 is improved.

FIG. 3B illustrates an enlarged partial view of a section of the balun transformer 102ashown in FIG. 3A. In the illustrated example, FIG. 3B shows a close up view of the primary rectangular conductor 203e and the secondary rectangular conductor 205d-205c. Each of the primary rectangular conductors 203 maybe defined by a height h1. For example, as illustrated in FIG. 3B, height h1 extends from a top surface of the primary rectangular conductor 203e to a bottom surface of the primary rectangular conductor 203e. In one embodiment, height h1 can be about ⅝″. In other embodiments, height h1 is between about 12 mm and about 25 mm. In another embodiment, each of the primary rectangular conductors 203 maybe defined by a width w1. For example, as further illustrated in illustrated in FIG. 3B, width w1 extends from a first side 208a of the primary rectangular conductor 203e to a second side 208b of the primary rectangular conductor 203e. In one embodiment, width wl can be about 5/3241 . In other embodiments, width w1 is between about 3 mm and about 6 mm.

In some embodiments, the primary rectangular conductor 203 may include a radius along its respective edges. For example, as shown in FIG. 3B, an edge radius of the primary rectangular conductor 203e is defined by a radius r1. In one embodiment, the radius r1 can be about 1.6 mm. In other embodiments, radius r1 is between about 0.3 mm to about a full radius of the maximum width w1. By including a radius along the edges of the primary rectangular conductor 203 or substantially rounding off the edges of the primary rectangular conductor 203, it is possible to prevent electrical arcing that may possibly occur.

As further illustrated in FIG. 3B, each of the secondary rectangular conductors 205 maybe defined by a height h2. For example, as shown in the figure, height h2 extends from a top surface of the secondary rectangular conductor 205e to a bottom surface of the secondary rectangular conductor 205e. In one embodiment, height h2 can be about ⅝″. In other embodiments, height h2 is between about 12 mm to about 25 mm. In another embodiment, each of the secondary rectangular conductors 205 maybe defined by a width w2. For example, width w2 extends from a first side 210a of the secondary rectangular conductor 205e to a second side 210b of the secondary rectangular conductor 205e. In one embodiment, width w2 can be about 5/32″. In other embodiments, width w2 between about 3 mm to about 6 mm.

In some embodiments, the secondary rectangular conductor 205 may include a radius along its respective corners. For example, an edge of the secondary rectangular conductor 205cis defined by a radius r2. In one embodiment, the radius r2 can be about 1.6 mm. In other embodiments, radius r2 is between about 0.3 mm to about a full radius of the maximum width w2. By including a radius along the corners of the secondary rectangular conductor 205 or substantially rounding off the corners of the secondary rectangular conductor 205, it is possible to prevent electrical arcing that may occur.

As further shown in FIG. 3B, the primary rectangular conductor 203 and the secondary rectangular conductor 205 are interleaved in a spaced apart orientation, such that one or two sides of each of the primary rectangular conductor 203 and the secondary rectangular conductors 205 are adjacent to one another. For example, as illustrated in FIG. 3B, the secondary rectangular conductor 205d has two sides that are adjacent to the sides of the primary rectangular conductor. In particular, the first side 210a of the secondary rectangular conductor 205d is adjacent to the second side 208b of the primary rectangular conductor 203d (not shown) and the second side 210b of the secondary rectangular conductor 205d is adjacent to the first side 208a of the primary rectangular conductor 203c. Further, the primary rectangular conductor 203c has two sides that are adjacent to the sides of the secondary rectangular conductor 205. In particular, the first side 208a of the primary rectangular conductor 203e is adjacent to the second side 210b of the secondary rectangular conductor 205d and the second side 208b of the primary rectangular conductor 203e is adjacent to the first side 210a of the secondary rectangular conductor 205c.

Further, the secondary rectangular conductor 205e has one side (e.g., first side 210a) that is adjacent to the side of the primary rectangular conductor 203e (e.g., second side 208b where the opposing side is not adjacent to any sides of the primary rectangular conductor 203.

Accordingly, maintaining a configuration where the one or two sides of each of the primary rectangular conductor 203 and the secondary rectangular conductor 205 are flat and adjacent to one another results in the respective sides of the conductors to be substantially parallel to each other. Since the respective sides of the conductors are substantially parallel to each other and the shape of the conductors provide a large surface area, RF coupling between the primary coil 202 and the secondary coil 204 can be enhanced which can result a greater amount of power being transferred to the TCP coils 110 more effectively.

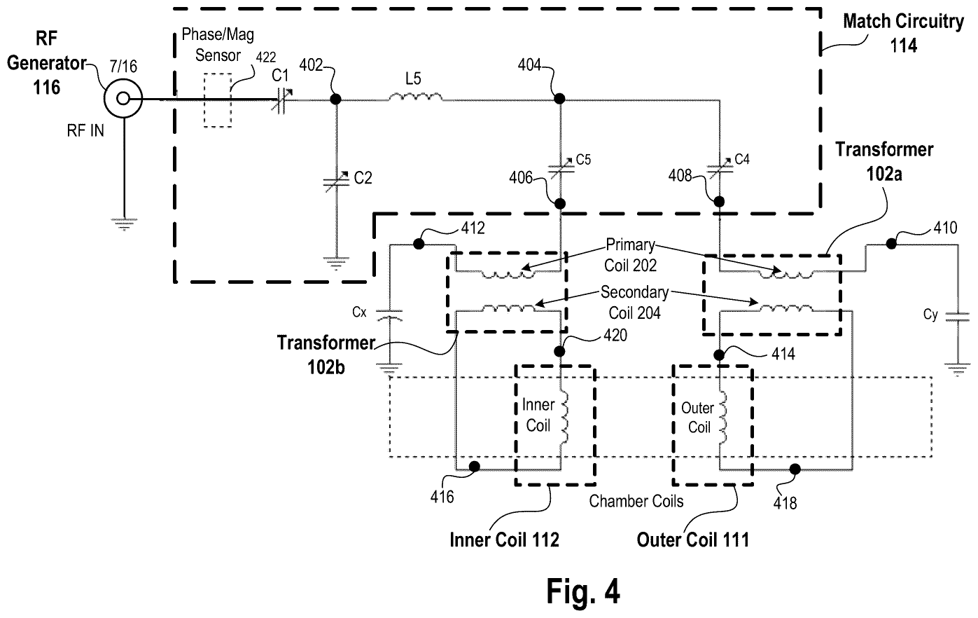

FIG. 4 is a schematic diagram illustrating the circuit topology of a TCCT match circuitry 114 coupled between an RF generator 116 and TCP coils 110 (outer coil 111 and inner coil 112) of a plasma processing system. In one embodiment, an RF generator 116 provides power to the TCCT match circuitry 114. In one embodiment, the TCCT match circuitry 114 is defined by a phase and magnitude sensor 422, a variable capacitor C1, node 402, a variable capacitor C2, inductor L5, node 404, a variable capacitor C5, node 406, a variable capacitor C4, and node 408. In other embodiments, the TCCT match may further be defined by transformers 102a-102b, node 412, a polarized capacitor Cx that in turn is connected to ground, node 410, and a fixed capacitor Cy that in turn is connected to ground.

As illustrated in FIG. 4, the phase and magnitude sensor 422 is coupled between the RF generator 116 and the variable capacitor C1. The variable capacitor C1 is coupled between the phase and magnitude sensor 422 and node 402. In some embodiments, the phase and magnitude sensor 422 is not included in the TCCT match circuitry 114. Node 402 connects to the variable capacitor C2, which in turn is connected to ground. Node 402 also connects to the inductor L5 which in turn connects to node 404. Node 404 connects to the variable capacitor C5 which in turn connects to node 406. Node 404 also connects to variable capacitor C4 which in turn connects to node 408.

In one embodiment, node 406 is coupled to the primary coil 202 of balun transformer 102b where the of balun transformer 102b is defined by the primary coil 202 and the secondary coil 204. As shown, node 406 is coupled to the second connection leg 202b of the primary coil 202. Further, node 412 is coupled to the first connection leg 202a of the primary coil 202. Node 412 connects to a polarized capacitor Cx that in turn is connected to ground. In one embodiment, node 408 is coupled to the primary coil 202 of balun transformer 102a where the of balun transformer 102a s defined by a primary coil 202 and secondary coil 204. Node 408 is coupled to the second connection leg 202b of the primary coil 202. Further, node 410 is coupled to the first connection leg 202a of the primary coil 202. Node 410 connects to a fixed capacitor Cy that in turn is connected to ground.

With continued reference to the balun transformer 102b shown in FIG. 4, the first connection leg 204a of the secondary coil 204 connects to node 416, which in turn connects to a first end of the inner coil 112. Further, the second connection leg 204b of the secondary coil 204 connects to node 420, which in turn connects to a second end of the inner coil 112. With reference to balun transformer 102a, a first connection leg 204a of the secondary coil 204 connects to node 418, which in turn connects to a first end of the outer coil 111. Further, the second connection leg 204b of the secondary coil 204 connects to node 414, which in turn connects to a second end of the outer coil 111.

In one embodiment, the variable capacitor C1 is rated at approximately 20 to 500 pF. In one embodiment, the variable capacitor C2 is rated at about 20 to 500 pF. In one embodiment, the inductor L5 is rated at about 0.3 uH. In one embodiment, the variable capacitor C5 is rated at about 100 to 1500 pF. In one embodiment, the variable capacitor C4 is rated at about 50 to 500 pF. In one embodiment, the polarized capacitor Cx is rated at about 268 pF. In one embodiment, the fixed capacitor Cy is rated at about 125 pF.

Broadly speaking, the circuit described with reference to FIG. 4 provides for improvements in RF power efficiency. The design of the balun transformers 102a-102b and the arrangement of the electrical components (described with reference to FIG. 4) improved power transfer efficiency, and in turn enhanced performance in wafer etch uniformity and power consumption.

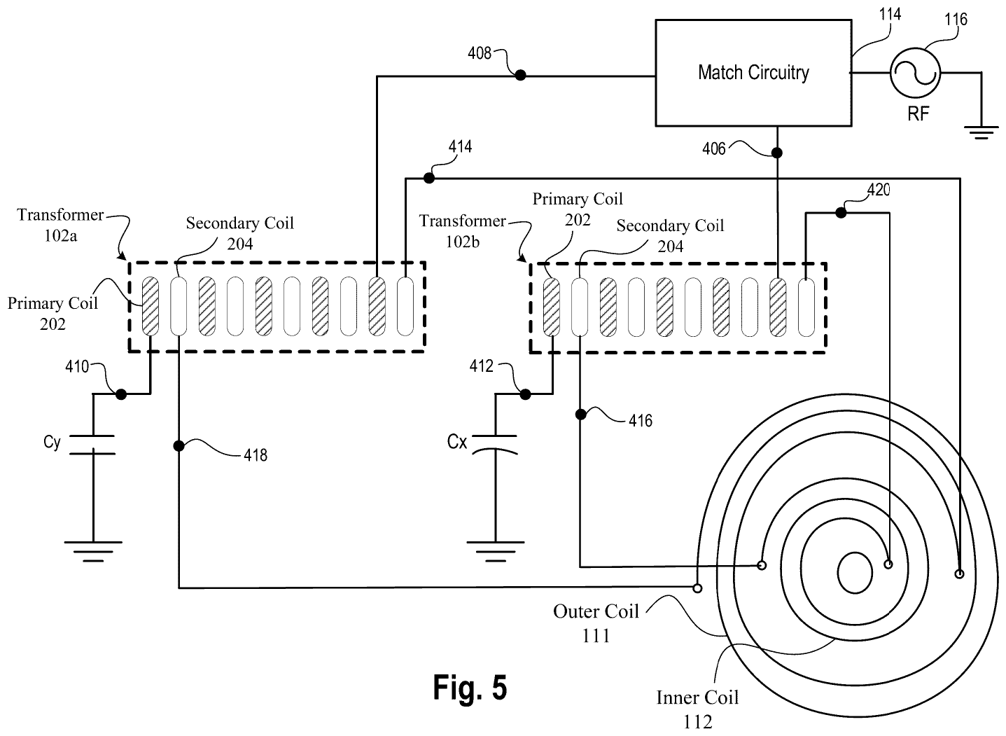

FIG. 5 is a schematic illustrating a portion of the plasma processing system. As shown, the balun transformers 102a-102b are coupled between the TCCT match circuitry 114 and the TCP coils 110 (e.g., outer coil 111 and inner coil 112). During plasma processing operations, the RF generator 116 activated which provides power to the TCCT match circuitry 114 which controls the operation of the balun transformers 102a-102b and the TCP coils 110 in which etching is performed. The TCCT match circuitry 114 is coupled to node 408 which in turn is coupled to the primary coil 202 of balun transformer 102a. In particular, node 408 is coupled to the second connection leg 202b of the primary coil 202.

With continued reference to balun transformer 102a, the first connection leg 202a of the primary coil 202 is coupled to node 410 which in turn connects to the fixed capacitor Cy and to ground. In one implementation, the first connection leg 204a of the secondary coil 204 is coupled to node 418, which in turn connects to a first end of the outer coil 111. Further, the second connection leg 204b of the secondary coil 204 is coupled to node 414, which in turn connects to a second end of the outer coil 111.

As further illustrated in FIG. 5, with reference to the TCCT match circuitry 114, the TCCT match circuitry 114 is coupled to node 406 which in turn is coupled to the primary coil 202 of balun transformer 102b. In particular, node 406 is coupled to the second connection leg 202b of the primary coil 202. Further, with reference to balun transformer 102b, the first connection leg 202a of the primary coil 202 is coupled to node 412 which in turn connects to the polarized capacitor Cx and to ground. In one embodiment, the first connection leg 204a of the secondary coil 204 is coupled to node 416, which in turn connects to a first end of the inner coil 112. Further, the second connection leg 204b of the secondary coil 204 is coupled to node 420, which in turn connects to a second end of the inner coil 112.

Accordingly, the configuration of the balun transformers 102 and the integration of the balun transformers 102 within the circuitry as described above with reference to FIG. 4 and FIG. 5 can enable improved etch uniformity along a wafer. For example, during plasma proccing operations, the system can deliver a higher amount of power to the TCP coils 110 more effectively which in turn improves etch uniformity on the wafer. In one embodiment, with the balun transformers 102 integrated within the plasma processing system, the balun transformers 102 can transfer about 6,000 Watts to the TCP coils 110.

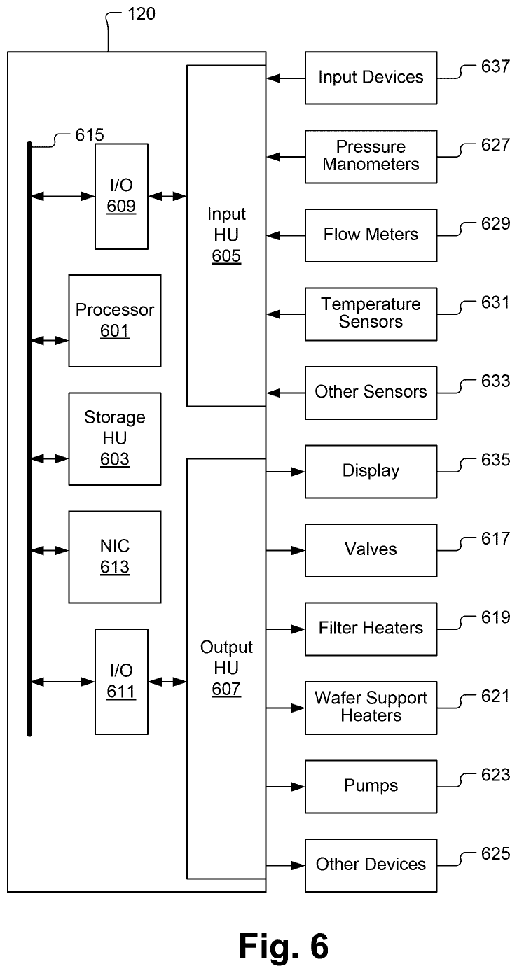

FIG. 6 shows an example schematic of the control system 120 of FIG. 1, in

accordance with some embodiments. In some embodiments, the control system 120 is configured as a process controller for controlling the semiconductor fabrication process performed in a plasma processing system. In various embodiments, the control system 120 includes a processor 601, a storage hardware unit (HU) 603 (e.g., memory), an input HU 605, an output HU 607, an input/output (I/O) interface 609, an I/O interface 611, a network interface controller (NIC) 613, and a data communication bus 615. The processor 601, the storage HU 603, the input HU 605, the output HU 607, the I/O interface 609, the I/O interface 611, and the NIC 613 are in data communication with each other by way of the data communication bus 615. The input HU 605 is configured to receive data communication from a number of external devices. Examples of the input HU 605 include a data acquisition system, a data acquisition card, etc. The output HU 607 is configured to transmit data to a number of external devices.

An example of the output HU 607 is a device controller. Examples of the NIC 613 include a network interface card, a network adapter, etc. Each of the I/O interfaces 609 and 611 is defined to provide compatibility between different hardware units coupled to the I/O interface. For example, the I/O interface 609 can be defined to convert a signal received from the input HU 605 into a form, amplitude, and/or speed compatible with the data communication bus 615. Also, the I/O interface 607 can be defined to convert a signal received from the data communication bus 615 into a form, amplitude, and/or speed compatible with the output HU 607. Although various operations are described herein as being performed by the processor 601 of the control system 120, it should be understood that in some embodiments various operations can be performed by multiple processors of the control system 120 and/or by multiple processors of multiple computing systems in data communication with the control system 120.

In some embodiments, the control system 120 is employed to control devices in various wafer fabrication systems based in-part on sensed values. For example, the control system 120 may control one or more of valves 617, filter heaters 619, wafer support structure heaters 621, pumps 623, and other devices 625 based on the sensed values and other control parameters. The valves 617 can include valves associated with control of a backside gas supply system, a process gas supply system, and a temperature control fluid circulation system. The control system 120 receives the sensed values from, for example, pressure manometers 627, flow meters 629, temperature sensors 631, and/or other sensors 633, e.g., voltage sensors, current sensors, etc. The control system 120 may also be employed to control process conditions within the plasma processing system during performance of plasma processing operations on the wafer 104. For example, the control system 120 can control the type and amounts of process gas(es) supplied from the process gas supply system to the plasma process chamber. Also, the control system 120 can control operation of a power supply for the clamp electrode(s). The control system 120 can also control operation of a lifting device for the lift pins. The control system 120 also controls operation of the backside gas supply system and the temperature control fluid circulation system. The control system 120 also controls operation of pump that controls removal of gaseous byproducts from the chamber 102. It should be understood that the control system 120 is equipped to provide for programmed and/or manual control any function within the plasma processing system.

In some embodiments, the control system 120 is configured to execute computer programs including sets of instructions for controlling process timing, process gas delivery system temperature, and pressure differentials, valve positions, mixture of process gases, process gas flow rate, backside cooling gas flow rate, chamber pressure, chamber temperature, wafer support structure temperature (wafer temperature), RF power levels, RF frequencies, RF pulsing, impedance matching system settings, cantilever arm assembly position, bias power, and other parameters of a particular process. Other computer programs stored on memory devices associated with the control system 120 may be employed in some embodiments. In some embodiments, there is a user interface associated with the control system 120. The user interface includes a display 635 (e.g., a display screen and/or graphical software displays of the apparatus and/or process conditions), and user input devices 637 such as pointing devices, keyboards, touch screens, microphones, etc.

Software for directing operation of the control system 120 may be designed or configured in many different ways. Computer programs for directing operation of the control system 120 to execute various wafer fabrication processes in a process sequence can be written in any conventional computer readable programming language, for example: assembly language, C, C++, Pascal, Fortran or others. Compiled object code or script is executed by the processor 601 to perform the tasks identified in the program. The control system 120 can be programmed to control various process control parameters related to process conditions such as, for example, filter pressure differentials, process gas composition and flow rates, backside cooling gas composition and flow rates, temperature, pressure, plasma conditions, such as RF power levels and RF frequencies, bias voltage, cooling gas/fluid pressure, and chamber wall temperature, among others. Examples of sensors that may be monitored during the wafer fabrication process include, but are not limited to, mass flow control modules, pressure sensors, such as the pressure manometers 627 and the temperature sensors 631. Appropriately programmed feedback and control algorithms may be used with data from these sensors to control/adjust one or more process control parameters to maintain desired process conditions.

In some implementations, the control system 120 is part of a broader fabrication control system. Such fabrication control systems can include semiconductor processing equipment, including a processing tool, chambers, and/or platforms for wafer processing, and/or specific processing components, such as a wafer pedestal, a gas flow system, etc. These fabrication control systems may be integrated with electronics for controlling their operation before, during, and after processing of the wafer. The control system 120 may control various components or subparts of the fabrication control system. The control system 120, depending on the wafer processing requirements, may be programmed to control any of the processes disclosed herein, including the delivery of processing gases, the delivery of backside cooling gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the control system 120 may be defined as electronics having various integrated circuits, logic, memory, and/or software that receive instructions, issue instructions, control operation, enable wafer processing operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the control system 120 in the form of various individual settings (or program files), defining operational parameters for carrying out a particular process on the wafer within the system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The control system 120, in some implementations, may be a part of or coupled to a computer that is integrated with, coupled to the plasma processing system, or otherwise networked to the system, or a combination thereof. For example, the control system 120 may be in the “cloud” of all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to the system over a network, which may include a local network or the Internet.

The remote computer may include a user interface that enables entry or programming of parameters and/or settings, which are then communicated to the system from the remote computer. In some examples, the control system 120 receives instructions in the form of data, which specify parameters for each of the processing steps to be performed during one or more operations. It should be understood that the parameters may be specific to the type of process to be performed within the plasma processing system. Thus, as described above, the control system 120 may be distributed, such as by comprising one or more discrete controllers that are networked together and working towards a common purpose, such as the processes and controls described herein. An example of a distributed controller for such purposes would be one or more integrated circuits on the plasma processing system in communication with one or more integrated circuits located remotely (such as at the platform level or as part of a remote computer) that combine to control a process performed on the plasma processing system.

Without limitation, example systems that the control system 120 can interface with may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the control system 120 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Embodiments described herein may also be implemented in conjunction with various computer system configurations including hand-held hardware units, microprocessor systems, microprocessor-based or programmable consumer electronics, minicomputers, mainframe computers and the like. Embodiments described herein can also be implemented in conjunction with distributed computing environments where tasks are performed by remote processing hardware units that are linked through a network. It should be understood that the embodiments described herein, particularly those associated with the control system 120, can employ various computer-implemented operations involving data stored in computer systems. These operations are those requiring physical manipulation of physical quantities. Any of the operations described herein that form part of the embodiments are useful machine operations. The embodiments also relate to a hardware unit or an apparatus for performing these operations. The apparatus may be specially constructed for a special purpose computer. When defined as a special purpose computer, the computer can also perform other processing, program execution or routines that are not part of the special purpose, while still being capable of operating for the special purpose. In some embodiments, the operations may be processed by a general purpose computer selectively activated or configured by one or more computer programs stored in the computer memory, cache, or obtained over a network. When data is obtained over a network, the data may be processed by other computers on the network, e.g., a cloud of computing resources.

Various embodiments described herein can be implemented through process control instructions instantiated as computer-readable code on a non-transitory computer-readable medium. The non-transitory computer-readable medium is any data storage hardware unit that can store data, which can be thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes, and other optical and non-optical data storage hardware units. The non-transitory computer-readable medium can include computer-readable tangible medium distributed over a network-coupled computer system so that the computer-readable code is stored and executed in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments. What is claimed is:

1. A balun transformer for use in powering an electrode coil of a semiconductor chamber, the balun transformer comprising:
a primary coil having a primary winding between a primary first end and a primary second end, the primary winding defined from a primary rectangular conductor; and
a secondary coil having a secondary winding between a secondary first end and a secondary second end, the secondary winding defined from a secondary rectangular conductor;
wherein the primary rectangular conductor and the secondary rectangular conductor are interleaved in a spaced apart orientation, such that one or two sides of each of the primary rectangular conductor and the secondary rectangular conductor are adjacent to one another.

2. The balun transformer of claim 1, wherein the primary rectangular conductor includes a first connection leg and a second connection leg for electrically connecting to a match network, wherein said match network is coupled to a radio frequency (RF) source.

3. The balun transformer of claim 2, wherein a capacitor is coupled between the first connection leg of the primary rectangular conductor and ground.

4. The balun transformer of claim 1, wherein the secondary rectangular conductor includes a first connection leg and a second connection leg for electrically connecting, respectively, to a first end of the electrode coil and a second end of the electrode coil.

5. The balun transformer of claim 1, wherein the primary coil and the secondary coil are embedded in a dielectric encasing.

6. The balun transformer of claim 1, wherein the one or two sides of each of the primary rectangular conductor and the secondary rectangular conductor are substantially parallel to one another.

7. The balun transformer of claim 1, wherein the primary rectangular conductor and the secondary rectangular conductor includes a radius along respective corners of said primary rectangular conductor and said secondary rectangular conductor.

8. The balun transformer of claim 1, wherein a distance extending from a side of the primary rectangular conductor to a side of an adjacent secondary rectangular conductor is between about 2 mm and about 6 mm.

9. The balun transformer of claim 1, wherein the primary rectangular conductor and the secondary rectangular conductor has a height of about 16 mm.

10. The balun transformer of claim 1, wherein the primary rectangular conductor and the secondary rectangular conductor has a width of about 4 mm.

11. The balun transformer of claim 1, wherein a number of turns in the primary coil is the same as a number of turns in the secondary coil.

12. The balun transformer of claim 1, wherein a radio frequency (RF) source activates a match network to enable the balun transformer to transfer up to about 6,000 Watts to the electrode coil of the semiconductor chamber.

13. The balun transformer of claim 1, wherein respective sides of each of the primary rectangular conductor and the secondary rectangular conductor are substantially flat along the primary rectangular conductor of the primary winding and the secondary rectangular conductor of the secondary winding.

14. The balun transformer of claim 1, wherein the primary coil and the secondary coil is made of a C110 copper material and silver plated.

15. A system, comprising:
a process chamber having a dielectric window, and said dielectric window being oriented over a substrate support;
a coil defined by a first electrode coil and a second electrode coil, the coil oriented over the dielectric window;
a first balun transformer for connecting to the first electrode coil, the first balun transformer including,
a first primary coil having a first primary winding defined from a first primary rectangular conductor; and
a first secondary coil having a first secondary winding defined from a first secondary rectangular conductor;
wherein the first primary rectangular conductor and the first secondary rectangular conductor are interleaved in a spaced apart orientation, such that one or two sides of each of the first primary rectangular conductor and the first secondary rectangular conductor are adjacent to one another, and
a second balun transformer for connecting to the second electrode coil, the second balun transformer including,
a second primary coil having a second primary winding defined from a second primary rectangular conductor;
a second secondary coil having a second secondary winding defined from a secondary rectangular conductor;
wherein the second primary rectangular conductor and the second secondary rectangular conductor are interleaved in a spaced apart orientation, such that one or two sides of each of the second primary rectangular conductor and the second secondary rectangular conductor are adjacent to one another.

16. The system of claim 15, wherein the first primary rectangular conductor of the first balun transformer and the second primary rectangular conductor of the second balun transformer each respectively includes a first connection leg and a second connection leg for electrically connecting to a match network, wherein said match network is coupled to a radio frequency (RF) source.

17. The system of claim 16, wherein a capacitor is coupled between the first connection leg of the first primary rectangular conductor and ground.

18. The system of claim 16, wherein a capacitor is coupled between the first connection leg of the second primary rectangular conductor and ground.

19. The system of claim 15, wherein respective sides of each of the first primary rectangular conductor, the first secondary rectangular conductor, the second primary rectangular conductor, and the second secondary rectangular conductor are substantially flat.

20. The system of claim 15, wherein the first primary coil, the first secondary coil, the second primary coil, and the second secondary coil are embedded in a dielectric encasing.
